(19) United States
(12) Patent Application Publication
(10) Pub. No.: US 2023/0225125 A1
(43) Pub. Date: Jul. 13, 2023

(54) THREE-DIMENSIONAL MEMORY STRUCTURE AND MANUFACTURING METHOD FOR THE SAME

(71) Applicant: MACRONIX INTERNATIONAL CO., LTD., Hsinchu (TW)

(72) Inventors: I-Chen YANG, Miaoli County (TW); Yao-Wen CHANG, Zhubei City (TW); Guan-Wei WU, Zhubei City (TW)

(21) Appl. No.: 17/574,622

(22) Filed: Jan. 13, 2022

(51) Int. Cl. H01L 27/11582

(52) U.S. Cl. CPC H01L 27/11582

(57) ABSTRACT

A three-dimensional memory structure and a manufacturing method for the same are provided. The three-dimensional memory structure includes a channel layer, gate electrode layers and charge trapping layers. The charge trapping layers are between a channel sidewall surface of the channel layer and electrode sidewall surfaces of the gate electrode layers. The charge trapping layers are arranged in a discontinuous manner along a direction.

### BACKGROUND

### Technical Field

The disclosure relates to a three-dimensional memory structure and a manufacturing method for the same.

### Description of the Related Art

A three-dimensional memory device, such as a three-dimensional flash memory device with single-gate memory cells, double gate memory cells, and surrounding gate memory cells, including memory cells in a three-dimensional array constructed in a multi-layer stack with vertical channels, can achieve higher storage density and better data storage reliability and operating speed.

A three-dimensional memory structure, as shown in a cross-section view of FIG. 10A, comprises a data storage layer, gate electrode layers 300 (word lines), a channel layer 400, insulating layers 500 and a dielectric element 600. The data storage layer 800 comprises a high-k dielectric layer 200 (such as aluminum oxide), a charge trapping layer 810, a tunneling layer 820 and a blocking layer 830. FIG. 10B shows a three-dimensional view of the channel layer 400 and the charge trapping layer 810 of the three-dimensional memory structure. The charge trapping layer 810 has a structure extending continuously along a direction VD. Therefore, it is possible for a charge in a programmed memory cell to move in the charge trapping layer 810 towards adjacent upper and lower memory cells.

Moreover, with the increase in applications, the demand for the three-dimensional memory device tends to be smaller in size and larger in memory capacity. In order to increase the storage density of the three-dimensional memory device, it is necessary to minimize the element dimension of the multi-layer stack structure. For example, a gate length (i.e. a size of the gate electrode layer 300 in the direction VD) and a gate gap distance (i.e. a gap distance of the gate electrode layers 300 in the direction VD) can be reduced. However, a smaller gate gap distance would result in a stronger bias interference to a charge of a programmed memory cell from the gate electrode layers 300 corresponding to adjacent upper and lower memory cells, making the charge of the programmed memory cell moving. The threshold voltage (Vt) of the memory cell would be changed due to the charge movement. In addition, the data retention of the memory cell and the reliability of the memory device are degraded.

In addition, the three-dimensional memory structure as shown in FIG. 10A is manufactured by a method forming the high-k dielectric layer 200 in slits of the stacked structure, and then forming the gate electrode layer 300 on the high-k dielectric layer 200 in the slits. However, the thickness of the high-k dielectric layer 200 on upper electrode surfaces 300U and lower electrode surfaces 300B of the gate electrode layers 300 hinders the shrinkage of the gap distance of the gate electrode layers 300 in the direction VD.

### SUMMARY

The present disclosure relates to a three-dimensional memory structure and a manufacturing method for the same.

According to an embodiment, a three-dimensional memory structure is disclosed. The three-dimensional memory structure comprises a channel layer, gate electrode layers and charge trapping layers. The charge trapping layers are between a channel sidewall surface of the channel layer and electrode sidewall surfaces of the gate electrode layers. The charge trapping layers are arranged in a discontinuous manner along a direction.

According to another embodiment, a manufacturing method for a three-dimensional memory structure is disclosed. The manufacturing method comprises the following steps. A channel layer is formed. Charge trapping layers are formed. Gate electrode layers are formed. The charge trapping layers are between a channel sidewall surface of the channel layer and electrode sidewall surfaces of the gate electrode layers. The charge trapping layers are arranged in a discontinuous manner along a direction.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1A illustrates a cross-section view of a three-dimensional memory structure in an embodiment.

FIG. 1B shows a three-dimensional view of charge trapping layers and a channel layer of the three-dimensional memory structure in FIG. 1A.

FIG. 2 to FIG. 9 illustrate a manufacturing method for a three-dimensional memory structure in an embodiment.

FIG. 10A illustrates a cross-section view of a three-dimensional memory structure of prior art.

FIG. 10B shows a three-dimensional view of a charge trapping layer and a channel layer of the three-dimensional memory structure of prior art in FIG. 10A.

### DETAILED DESCRIPTION

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

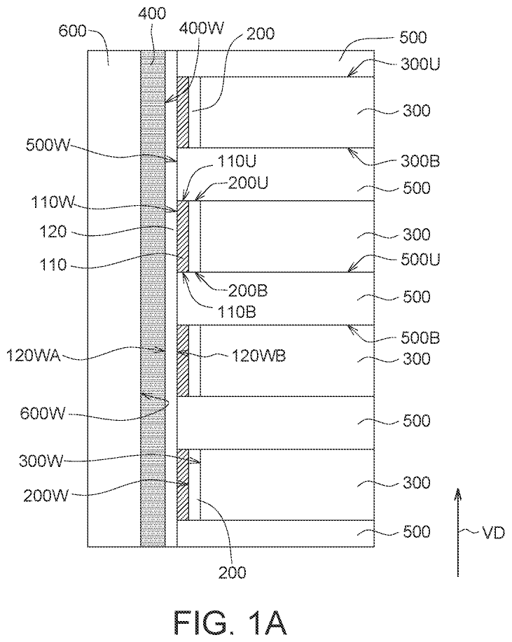

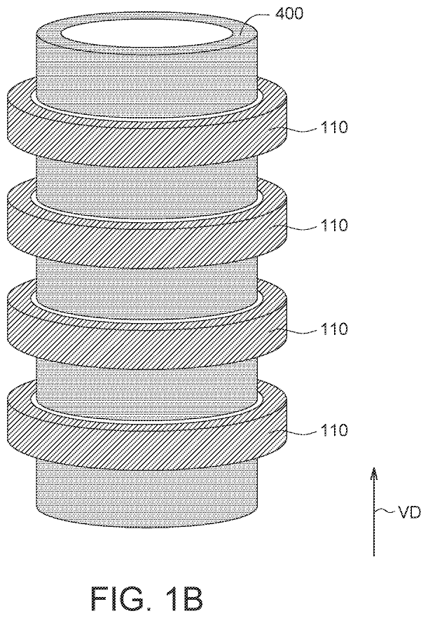

A three-dimensional memory structure in an embodiment is illustrated with referring to FIG. 1A and FIG. 1B.

FIG. 1A is referred to, which is a cross-section view of the three-dimensional memory structure. The three-dimensional memory structure may comprise a data storage layer, gate electrode layers 300, a channel layer 400, insulating layers 500 and a dielectric element 600. The data storage layer comprises high-k dielectric layers 200, charge trapping layers 110 and a tunneling layer 120. The gate electrode layers 300 and the insulating layers 500 are stacked alternately along a direction VD. The direction VC may be a vertical direction substantially orthogonal to an upper surface of a substrate, and the channel layer 400 may be referred to as a vertical direction, but the present disclosure is not limited thereto. The high-k dielectric layer 200 is between the charge trapping layer 110 and the gate electrode layer 300. The tunneling layer 120 is between a channel sidewall surface 400W of the channel layer 400 and memory sidewall surfaces 110W of the charge trapping layers 110, and is between the channel sidewall surface 400W and insulating sidewall surfaces 500W of the insulating layers 500. The channel layer 400 is between a dielectric sidewall surface 600W of the dielectric element 600 and a tunneling sidewall surface 120WA of the tunneling layer 120.

FIG. 1A and FIG. 1B are referred to. FIG. 1B shows a three-dimensional view of the charge trapping layers 110 and the channel layer 400 of the three-dimensional memory structure. In embodiments, the charge trapping layers 110 (or charge storage units) are disposed separately in different levels in the direction VD on the channel sidewall surface 400W of the channel layer 400. The charge trapping layers 110 are individual and discontinuous from each other. The charge trapping layers 110 are confined charge storage units. Therefore, the storage charge of the programmed unit cell would not shift. As such, the unit cells have stable data retention, and the memory device has good reliability. The gate length and the gate gap distance can be reduced without affecting operating efficiency of the memory device.

As shown in FIG. 1A, the charge trapping layer 110 is between a lower insulating surface 500B of the insulating layer 500 of an upper level and an upper insulating surface 500U of the insulating layer 500 of a lower level, and is between a dielectric sidewall surface 200W of the high-k dielectric layer 200 and a tunneling sidewall surface 120WB of the tunneling layer 120. The charge trapping layers 110 in different levels of the direction VD are separated from each other by the insulating layers 500, and are discontinuous with respect to each other. An upper memory surface 110U and a lower memory surface 110B of the charge trapping layer 110 may be adjoined with the insulating layers 500. The upper memory surface 110U of the charge trapping layer 110, an upper dielectric surface 200U of the high-k dielectric layer 200, and an upper electrode surface 300U of the gate electrode layer 300 are coplanar, in other words, are even with each other. The lower memory surface 110B of the charge trapping layer 110, a lower dielectric surface 200B of the high-k dielectric layer 200, and a lower electrode surface 300B of the gate electrode layer 300 are coplanar, in other words, are even with each other. The charge trapping layer 110, the high-k dielectric layer 200 and the gate electrode layer 300 in the same level have an identical height (i.e. size in the direction VD). The gate electrode layer 300 has only an electrode sidewall surface 300W with the charge trapping layer 110 thereon. The charge trapping layer 110 is not disposed on the upper electrode surface 300U and the lower electrode surface 300B of the gate electrode layer 300.

In embodiments, the gate electrode layer 300 has only the electrode sidewall surface 300W with the high-k dielectric layer 200 thereon. In other words, the high-k dielectric layer 200 is not disposed on the upper electrode surface 300U and the lower electrode surface 300B of the gate electrode layer 300. Therefore, the gate electrode layers 300 can have a smaller gap distance in the direction VD.

In embodiments, the three-dimensional memory structure can be a three-dimensional gate-all-around (GAA) structure. The three-dimensional memory structure can be applied for a NAND-type memory device or a NOR-type memory device.

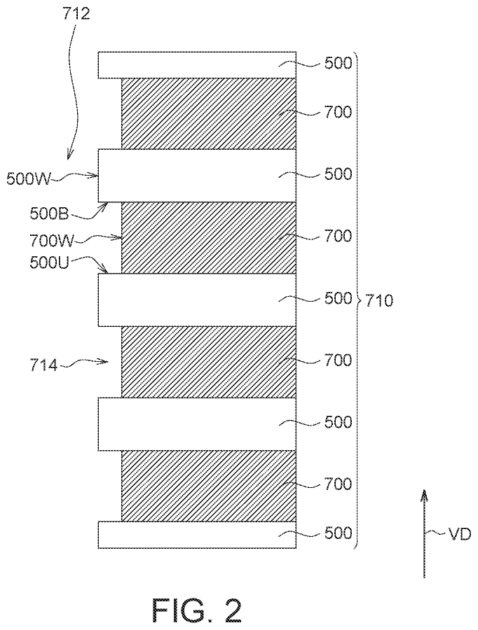

FIG. 2 to FIG. 9 illustrate a manufacturing method for the three-dimensional memory structure in an embodiment.

Referring to FIG. 2, material layers 700 and the insulating layers 500 are stacked alternately in the direction VD (e.g. vertical direction) to form a stacked structure 710 on the upper surface of the substrate. A material of the material layer 700 is different from a material of the insulating layer 500. In an embodiment, the material layer 700 comprises a nitride such as silicon nitride. The insulating layer 500 comprises an oxide such as silicon oxide. However, the present disclosure is not limited thereto.

The stacked structure 710 may be patterned to form an opening 712 exposing material sidewall surfaces of the material layers 700 and the insulating sidewall surfaces 500W of the insulating layers 500. An etching back step may be performed to the material layers 700 exposed by the opening 712 to form recesses 714. The recesses 714 are defined by material sidewall surfaces 700W of the material layers 700, and the upper insulating surfaces 500U and the lower insulating surfaces 500B of the insulating layers 500.

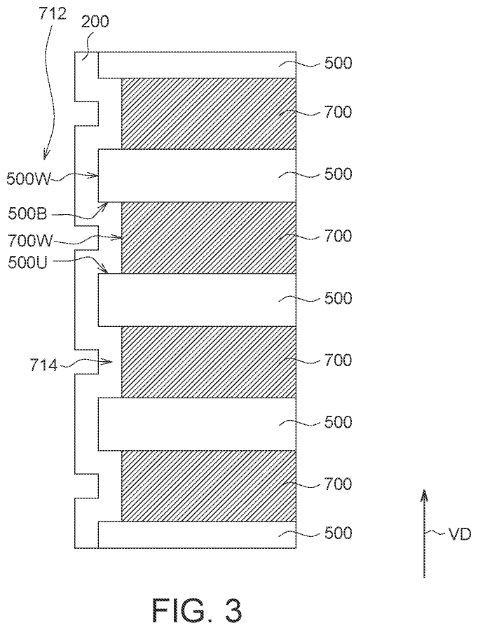

Referring to FIG. 3, the high-k dielectric layer 200 may be formed on the material sidewall surfaces 700W of the material layers 700, and the upper insulating surfaces 500U and the lower insulating surfaces 500B of the insulating layers 500 exposed by the recesses 714, and on the insulating sidewall surfaces 500W of the insulating layers 500 exposed by the opening 712 by using a deposition method. The high-k dielectric layer 200 may comprise aluminum oxide (Al₂O₃).

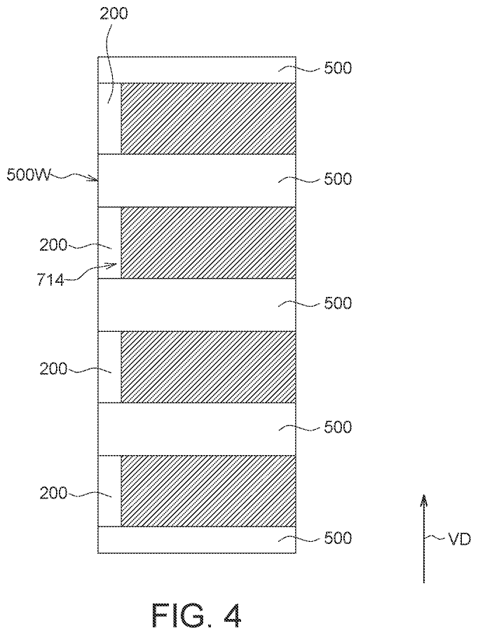

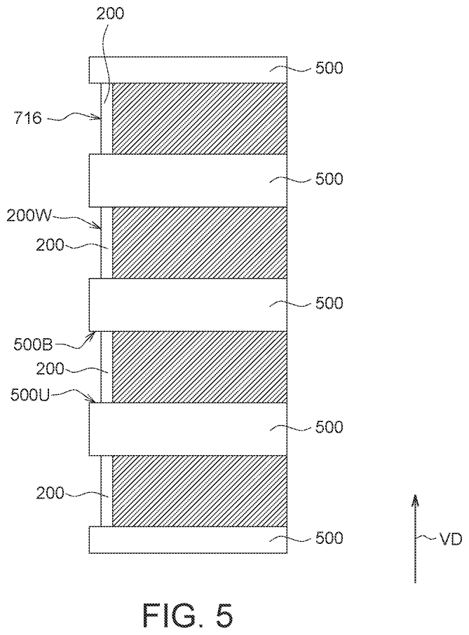

Referring to FIG. 4, an anisotropic etching step may be used to remove portions of the high-k dielectric layer 200 on the insulating sidewall surfaces 500W of the insulating layers 500. The high-k dielectric layers 200 in the recesses 714 are remained from the anisotropic etching step. An etching back step may be performed to the high-k dielectric layers 200 in the recesses 714 to form recesses 716 as shown in FIG. 5. The recesses 716 are defined by the dielectric sidewall surfaces 200W of the high-k dielectric layers 200, and the upper insulating surfaces 500U and the lower insulating surfaces 500B of the insulating layers 500.

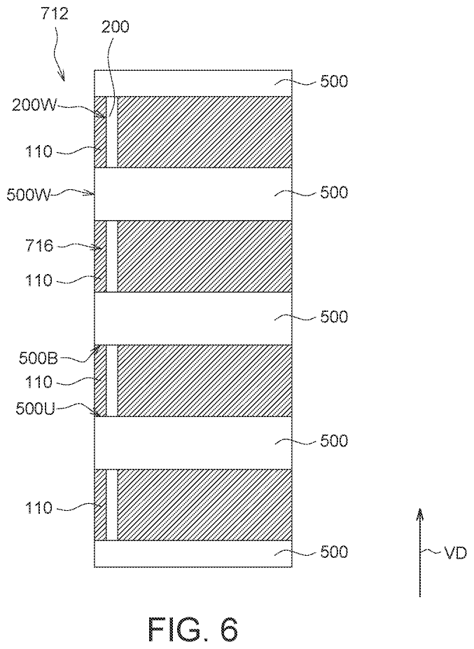

Referring to FIG. 6, the charge trapping layers 110 are formed in the recesses 716. In an embodiment, a charge trapping film may be formed on the dielectric sidewall surfaces 200W of the high-k dielectric layers 200 and the upper insulating surfaces 500U and the lower insulating surfaces 500B of the insulating layers 500 exposed by the recesses 716, and on the insulating sidewall surfaces 500W of the insulating layers 500 exposed by the opening 712. Then, an anisotropic etching method may be used to remove portions of the charge trapping film on the insulating sidewall surfaces 500W of the insulating layers 500, remaining the charge trapping layers 110 in the recesses 716. The charge trapping layers 110 may comprise silicon nitride (e.g. Si₃N₄), or other suitable materials such as hafnium dioxide (HfO₂).

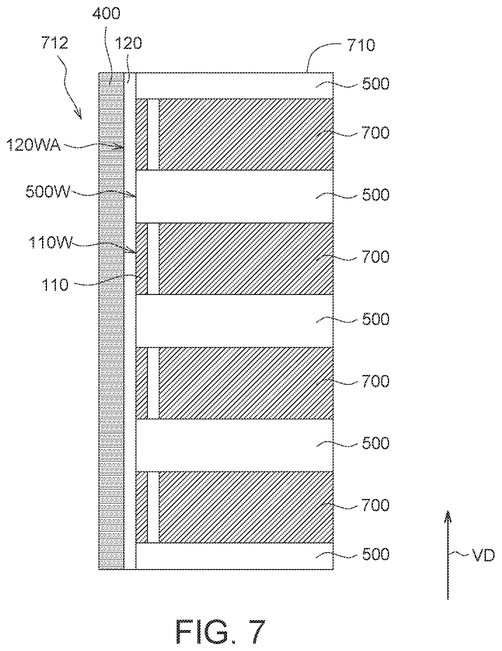

Referring to FIG. 7, the tunneling layer 120 is formed on the insulating sidewall surfaces 500W of the insulating layers 500 and the memory sidewall surfaces 110W of the charge trapping layers 110 exposed by the opening 712 of the stacked structure 710. The tunneling layer 120 may comprise a single-layer oxide such as a single-layer silicon oxide, or a single-layer silicon oxynitride. Otherwise, the tunneling layer 120 may comprise a two-layer oxide structure, such as a two-layer structure consisting of a silicon oxide layer and a silicon oxynitride layer. Otherwise, the tunneling layer 120 may comprise a three-layer structure consisting of an oxide and a nitride, such as a three-layer structure consisting of two silicon oxide layers and one silicon nitride layer disposed between the two silicon oxide layers. The channel layer 400 is formed on the tunneling sidewall surface 120WA of the tunneling layer 120 exposed by the opening 712 of the stacked structure 710. The channel layer 400 may comprise polysilicon, single crystal silicon, silicon-germanium (SiGe), or other suitable semiconductor materials.

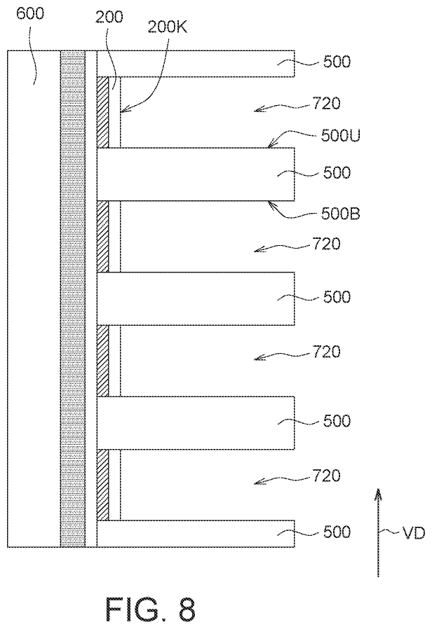

Referring to FIG. 8, the opening 712 of the stacked structure 710 is filled by the dielectric element 600 as shown in FIG. 7. The material layers 700 (which may be referred to as sacrificial layers) may be removed to form slits 720 between the insulating layers 500. The slits 720 may be defined by the upper insulating surfaces 500U and the lower insulating surfaces 500B of the insulating layers 500 and dielectric sidewall surfaces 200K of the high-k dielectric layers 200.

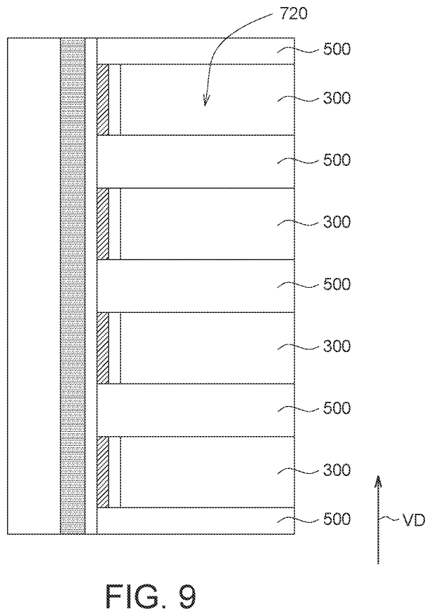

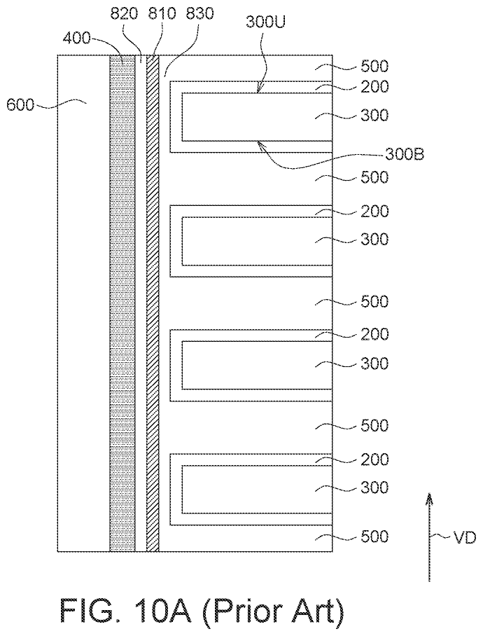

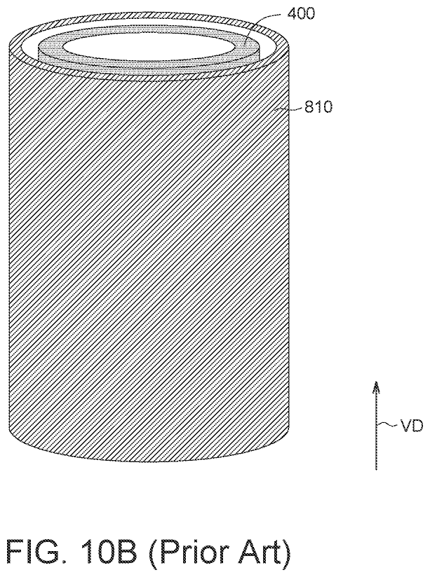

Referring to FIG. 9, the gate electrode layers 300 are formed in the slits 720. The gate electrode layers 300 may be metal electrodes.

According to the manufacturing method above, in embodiments, the high-k dielectric layers 200 are formed in opening 712 of the stacked structure 710 (referring to the manufacturing steps shown in FIG. 2 to FIG. 5), and then the slits 720 are formed (referring to the manufacturing step shown in FIG. 8) with being filled by the gate electrode layers 300 (referring to the manufacturing step shown in FIG. 9). The high-k dielectric layers 200 are not in the slits 720, and therefore the gate electrode layers 300 can be successfully filled into the slits 720. As such, the product yield and operating efficiency of the memory device can be improved.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A three-dimensional memory structure, comprising:
a channel layer;
gate electrode layers; and
charge trapping layers between a channel sidewall surface of the channel layer and electrode sidewall surfaces of the gate electrode layers, wherein the charge trapping layers are arranged in a discontinuous manner along a direction.

2. The three-dimensional memory structure according to claim 1, wherein each of the charge trapping layers and corresponding one of the gate electrode layers have an identical height.

3. The three-dimensional memory structure according to claim 1, wherein one of the charge trapping layers has an upper memory surface even with an upper electrode surface of one of the gate electrode layers.

4. The three-dimensional memory structure according to claim 1, wherein one of the charge trapping layers has a lower memory surface even with a lower electrode surface of one of the gate electrode layers.

5. The three-dimensional memory structure according to claim 1, wherein the gate electrode layers have only the electrode sidewall surfaces with the charge trapping layers thereon.

6. The three-dimensional memory structure according to claim 1, further comprising high-k dielectric layers, wherein each of the high-k dielectric layers is between corresponding one of the charge trapping layers and corresponding one of the gate electrode layers.

7. The three-dimensional memory structure according to claim 6, wherein each of the high-k dielectric layers and corresponding one of the gate electrode layers have an identical height.

8. The three-dimensional memory structure according to claim 6, wherein each of the high-k dielectric layers and corresponding one of the charge trapping layers have an identical height.

9. The three-dimensional memory structure according to claim 6, wherein the gate electrode layers have only the electrode sidewall surfaces with the high-k dielectric layers thereon.

10. The three-dimensional memory structure according to claim 6, wherein an upper memory surface of one of the charge trapping layers, an upper electrode surface of one of the gate electrode layers, and an upper dielectric surface of one of the high-k dielectric layers are coplanar.

11. The three-dimensional memory structure according to claim 6, wherein a lower memory surface of one of the charge trapping layers, a lower electrode surface of one of the gate electrode layers, and a lower dielectric surface of one of the high-k dielectric layers are coplanar.

12. The three-dimensional memory structure according to claim 1, further comprising insulating layers, wherein the insulating layers and the gate electrode layers are stacked alternately along the direction, the charge trapping layers are separated from each other by the insulating layers.

13. The three-dimensional memory structure according to claim 12, wherein an upper memory surface or a lower memory surface of one of the charge trapping layers is adjoined with one of the insulating layers.

14. The three-dimensional memory structure according to claim 1, further comprising a tunneling layer between the channel sidewall surface of the channel layer and memory sidewall surfaces of the charge trapping layers.

15. A manufacturing method for a three-dimensional memory structure, comprising:
forming a channel layer;
forming charge trapping layers; and
forming gate electrode layers, wherein the charge trapping layers are between a channel sidewall surface of the channel layer and electrode sidewall surfaces of the gate electrode layers, wherein the charge trapping layers are arranged in a discontinuous manner along a direction.

16. The manufacturing method for the three-dimensional memory structure according to claim 15, further comprising stacking material layers and insulating layers alternately along the direction, wherein recesses are defined by material sidewall surfaces of the material layers and upper insulating surfaces and lower insulating surfaces of the insulating layers, wherein the charge trapping layers are formed in the recesses.

17. The manufacturing method for the three-dimensional memory structure according to claim 16, further comprising forming high-k dielectric layers in the recesses, wherein the charge trapping layers are formed after the high-k dielectric layers.

18. The manufacturing method for the three-dimensional memory structure according to claim 16, further comprising after the forming the charge trapping layers, removing the material layers so as to define slits between the insulating layers, wherein the gate electrode layers are formed in the slits.

19. The manufacturing method for the three-dimensional memory structure according to claim 18, further comprising forming high-k dielectric layers in the recesses, wherein the slits are defined by the upper insulating surface and the lower insulating surface of the insulating layers and dielectric sidewall surfaces of the high-k dielectric layers.

20. The manufacturing method for the three-dimensional memory structure according to claim 16, further comprising before the forming the channel layer, forming a tunneling layer on insulating sidewall surface of the insulating layers and memory sidewall surfaces of the charge trapping layers, wherein the channel layer is formed on a tunneling sidewall surface of the tunneling layer.
